(19) United States
(12) Patent Application Publication
(10) Pub. No.: US 2011/0162706 A1
(43) Pub. Date: Jul. 7, 2011

(54) PASSIVATED POLYSILICON EMITTER SOLAR CELL AND METHOD FOR MANUFACTURING THE SAME

(75) Inventors: Peter G. Borden, San Mateo, CA (US); Li Xu, San Jose, CA (US); Tristan R. Holtam, Saratoga, CA (US); Vinay K. Shah, San Mateo, CA (US)

(73) Assignee: APPLIED MATERIALS, INC., Santa Clara, CA (US)

(21) Appl. No.: 12/983,846

(22) Filed: Jan. 3, 2011

Related U.S. Application Data
(60) Provisional application No. 61/292,106, filed on Jan. 4, 2010.

(51) Int. Cl. H01L 31/0216; H01L 31/18

(52) U.S. Cl. 136/256; 438/72; 118/58; 257/E31.119

(57) ABSTRACT

A method for manufacturing a polysilicon emitter solar cell with a passivating layer over its polysilicon emitter layer is disclosed. The method includes steps of preparing a substrate, forming a first polysilicon layer over the substrate, and forming a first passivating layer over the first polysilicon layer. Another embodiment of the present invention discloses a solar cell apparatus. The solar cell apparatus includes a substrate, a first polysilicon layer over the substrate, and a first passivating layer on first polysilicon layer.

### CROSS-REFERENCE TO RELATED APPLICATIONS

This application claims benefit of U.S. provisional patent application Ser. No. 61/292,106, filed Jan. 4, 2010, which is incorporated by reference herein.

### BACKGROUND OF THE INVENTION

1. Field of the Invention

Embodiments of the invention relate to a solar cell, and more particularly, to a solar cell with passivated polysilicon emitter and a method for manufacturing the same.

2. Description of the Related Art

Polysilicon emitter solar cells typically consist of polysilicon emitter deposited on a thin tunnel dielectric such as silicon dioxide. The thin tunnel dielectric generally serves to passivate the interface between the polysilicon emitter and an underlying substrate, and to block dopant diffusion from the polysilicon emitter into the substrate that forms a hyper-abrupt junction. It is worth noting that the passivation hereinafter is for insulating one layer from another.

A surface of the polysilicon emitter could be passivated to form a layer to reduce the recombination of electrons and holes. It is known that when the surface of the emitter is passivated a reverse saturation current (or dark current) of the emitter scales to

$$tan \frac{W}{L}$$

while the reverse saturation current scales to

$$cot \frac{W}{L}$$

when the surface of the polysilicon emitter is not passivated, where W and L refer to the thickness of the emitter and the length of the diffusion, respectively. Since it is desirable to have a thin polysilicon emitter (e.g., less than 200 nanometers) in order to minimize a light absorption thereof, the length of the diffusion will be far larger than the thickness of the polysilicon emitter. Therefore,

$$cot \frac{W}{L}$$

could be very big while its counterpart

$$tan \frac{W}{L}$$

is very small. As such, the reverse saturation current of the polysilicon emitter solar cell without the passivated surface can be significantly larger than that in the polysilicon emitter solar cell with the passivated surface. It is also known that a large reverse saturation current leads to a low opened-circuit voltage, which renders the polysilicon emitter solar cell without the passivated surface less than desired.

Therefore, there is a need for a polysilicon emitter solar cell with a passivated surface so that the reverse saturation current could be reduced as much as possible before a more desirable solar cell can be manufactured.

### SUMMARY OF THE INVENTION

Embodiments of the invention generally provide a method for forming a solar cell device, comprising forming a first polysilicon layer over a first surface of a substrate, heating the polysilicon layer to a first temperature, wherein the first temperature is adapted to cause the formed polysilicon layer to densify, and forming a first passivating layer over the first polysilicon layer. The method may also include the step of forming the first passivating layer by disposing a substrate in a processing region of a processing chamber, generating an RF plasma in the processing region, and flowing an oxygen containing gas into the processing region, wherein the first passivating layer and the first polysilicon layer are both formed in the processing region, and the first passivating layer is formed before removing the substrate from the processing region after forming the first polysilicon layer.

Embodiments may further provide a solar cell device, comprising a crystalline silicon substrate, a first tunnel layer disposed over a first surface of the crystalline silicon substrate, a first polysilicon layer disposed over the first tunnel layer, and a first passivating layer disposed over the first polysilicon layer.

Embodiments may further provide a polysilicon emitter solar cell having a passivating layer on a polysilicon emitter layer and a method for manufacturing the same. In one embodiment, the method contains steps of preparing a substrate, forming a first polysilicon layer over the substrate, and forming a first passivating layer over the first polysilicon layer. In another embodiment, a solar cell structure comprises a substrate, a first polysilicon layer over the substrate, and a first passivating layer over the first polysilicon layer. Embodiments also include forming a second passivating layer over another polysilicon layer and an associated step for doing such.

### BRIEF DESCRIPTION OF THE DRAWINGS

So that the manner in which the above recited features of the invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic diagram showing a polysilicon emitter solar cell according to one embodiment of the present invention.

FIG. 2 is a flow chart showing a process of manufacturing a polysilicon emitter solar cell according to one embodiment of the present invention.

FIG. 3 illustrates a plan view of a solar cell production line according to one embodiment described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein relate to a polysilicon emitter solar cell and a method for manufacturing the same. In particular, the embodiments described herein relate to a method of forming a passivating layer over the polysilicon emitter during a densification process performed during the formation of a high quality solar cell device. In general, the polysilicon emitter densification step is advantageous for two reasons. First, it reduces the resistivity of the polysilicon so that it can be used to conduct current to contact grid lines. Second, it reduces the amount of optical absorption of the polysilicon when the formed solar cell is placed in use. Therefore, by using the methods described herein, the polysilicon emitter is passivated without significant modification to the currently existing polysilicon emitter formation process, saving much of the time and investment, while also improving the solar cell device performance by reducing the chance for carrier recombination at the surface of the emitter structure.

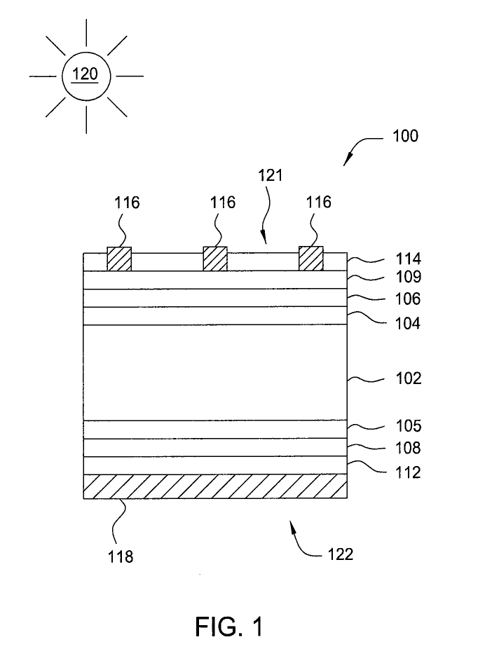

FIG. 1 illustrates one embodiment of a polysilicon emitter solar cell 100 according to one embodiment of the present invention. In one embodiment, the polysilicon emitter solar cell comprises a substrate 102, a tunnel layer 104, a first polysilicon layer 106, and an optional second polysilicon layer 108. In another embodiment, the polysilicon emitter solar cell comprises a substrate 102, tunnel layers 104 and 105, a first polysilicon layer 106, and an optional second polysilicon layer 108. As illustrated in FIG. 1, the tunnel layer 104 is disposed on a front side 121 of the substrate 102, and the other tunnel layer 105 is disposed on a back side 122 of the substrate 102. The front side of the substrate 102 generally refers to the side that receives the sun light 120. In one embodiment, the first polysilicon layer 106 and the optional second polysilicon layer 108 are formed on the tunnel layers 104 and 105, respectively. The solar cell 100 may further comprise a first passivating layer 109 on the first polysilicon layer 106, an optional second passivating layer 112 on the optional second polysilicon layer 108, an anti-reflection layer 114 on the first passivating layer 109, front contacts 116 on the anti-reflection layer 114, and back contact layer 118 on the optional second passivating layer 112 or on the optional second polysilicon layer 108. In one implementation, the polysilicon emitter solar cell 100 has a tunnel layer 104 and/or a tunnel layer 105 that comprises a dielectric material, such as silicon oxide (SiₓO_{y}), silicon nitride (SiN), silicon oxynitride (SiₓO_{y}N_{z}), silicon oxycarbon nitride (SiₓO_{y}C_{z}Nᵥ), hafnium oxide (HfₓO_{y}), hafnium oxynitride (HfₓO_{y}N_{z}), hafnium silicon oxide (HfₓSi_{y}O_{z}), hafnium silicon oxynitride (HfₓSi_{y}O_{z}Nᵥ), lanthanum oxide (LaₓO_{y}), lanthanum silicon oxide (LaₓSi_{y}O_{z}), lanthanum oxynitride (LaₓO_{y}N_{z}), lanthanum silicon oxynitride (LaₓSi_{y}O_{z}Nᵥ), aluminum oxide (AlₓO_{y}), combination thereof, or other similar material. In one embodiment, the substrate 102 is a crystalline silicon substrate, such as a monocrystalline substrate (e.g., Si<100> or Si<111>), a microcrystalline silicon substrate, multicrystalline silicon substrate, polycrystalline silicon substrate, a strained silicon substrate, an amorphous silicon substrate, or a doped or undoped polysilicon substrate.

The polysilicon layer 106 is the emitter portion of the of the solar cell 100, and the tunnel layers 104 passivates the interface between the polysilicon layer 106 and the substrate 102. The inclusion of the passivating layer 109 helps to reduce the reverse saturation current of the solar cell 100. In one embodiment, an optional passivating layer 112, which is typically thin (e.g., <12 Å), is used to reduce the surface recombination on the back side at the interface between the optional second polysilicon layer 108 and the back contact layer 118. In one implementation, the passivating layers 109, 112 are silicon dioxide (SiO₂), silicon nitride (SiN), silicon oxynitride (SiₓO_{y}N_{z}), silicon oxycarbon nitride (SiₓO_{y}C_{z}Nᵥ), or other similar layer. Although FIG. 1 shows two passivating layers 109 and 112 on both sides of the substrate 102, the solar cell structure may have only one passivating layer on the front side of the substrate 102.

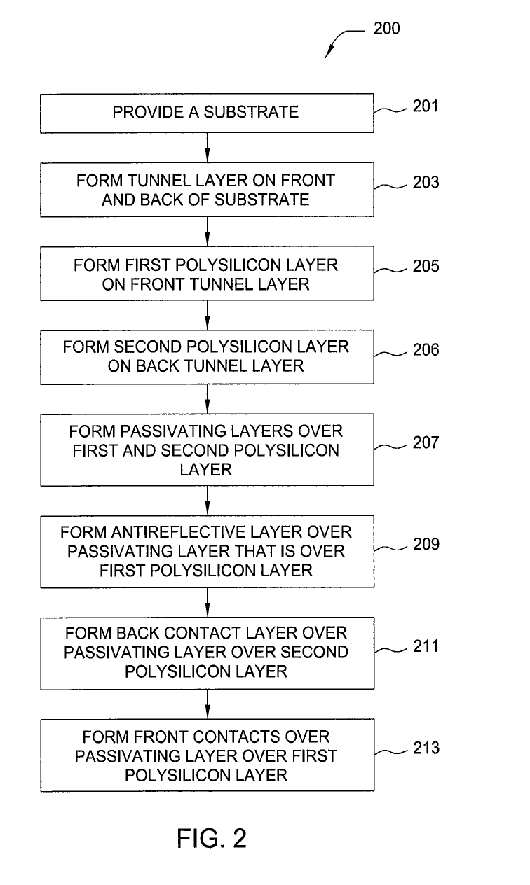

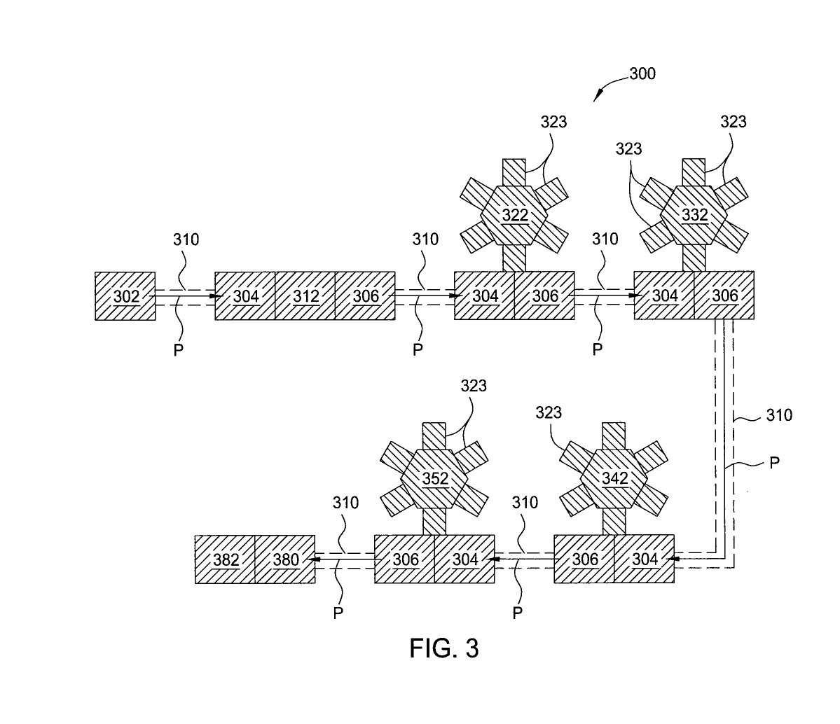

In conjunction with FIG. 1, FIG. 2 is a flow chart illustrating a process 200 of fabricating the solar cell 100 with the passivating layers 109 and 112 over the polysilicon layer 106 (i.e., polysilicon emitter) and the second polysilicon layer 108, according to one embodiment of the present invention. FIG. 3 depicts a schematic plan view of a solar cell production line 300 that may be used to perform the processes illustrated in FIG. 2 according to one embodiment of the invention. The solar cell production line 300 generally comprises a plurality of processing modules that are disposed along a path “P”, and are transferrably connected to each other by use of a plurality of transfer conveyors 310. In one embodiment, the transfer conveyors 310 are configured to serially transfer a plurality of substrates in a downstream direction following path “P”. In one configuration, the solar cell production line 300 includes a plurality of transfer conveyors 310 that are each configured to deliver substrates to a substrate loader 304 and receive substrates from a substrate unloader 306, so that the transferred substrates can be delivered to a processing chamber which is coupled to the substrate loader 304 and substrate unloader 306. The transfer conveyors 310 generally comprise a robotic device or conveyor that is adapted to move and position a substrate. In one example, the transfer conveyors 310 is a series of conventional substrate conveyors (e.g., roller type conveyor) and/or robotic devices (e.g., 6-axis robot, SCARA robot) that are configured to move and position the substrate as desired.

In step 201, the process starts with preparing the substrate 102 for the depositions of layers of films. In one embodiment, during step 201 a substrate tester 302 found in the production line is used to receive and test substrates that are to be loaded into the production line 300. In one embodiment, the substrate tester 302 may inspect, test and analyze the material properties and integrity of the substrate, which may include assuring that there are no cracks, chips or other physical defects, to determine if the substrate is in a state ready for processing. After the substrate is analyzed by the substrate tester 302, the substrate can then transferred to a first substrate loader 304 that is used to receive and orient the substrate so that it is ready for processing in an attached processing chamber.

In one embodiment of step 201, the surfaces of the substrate 102 are cleaned to remove any undesirable material or roughness. In one embodiment, as shown in FIG. 3, the first substrate loader 304 delivers the substrate to a wet cleaning chamber 312 so that the cleaning process can be performed on the substrate. The substrate 102 can be cleaned using a wet cleaning process in which they are sprayed, flooded, or immersed in a cleaning solution. The clean solution may be an SC1 cleaning solution, an SC2 cleaning solution, HF-last type cleaning solution, ozonated water solution, hydrofluoric acid (HF) and hydrogen peroxide (H₂O₂) solution, or other suitable and cost effective cleaning solution. The cleaning process may be performed on the substrate between about 5 seconds and about 600 seconds, such as about 30 seconds to about 240 second, for example about 120 seconds. After the cleaning process is performed on the substrate, the substrate may be unloaded using a substrate unloader 306 that is configured to receive the substrate from the wet cleaning chamber 312 and transfer the substrate to other processing module(s) disposed along the path “P” of the production line 300 using a plurality of transfer conveyors 310, as shown in FIG. 3. An example of a suitable wet cleaning chamber that can be adapted to perform step 201 is further described in the patent application Ser. No. 12/383,350, filed Mar. 23, 2009, which is incorporated by reference.

In step 203, the process 200 forms the tunnel layers 104 and 105 on the substrate 102 using a deposition system 322. In one embodiment, the deposition system 322 may comprise one or more chemical vapor deposition (CVD) chambers, one or more rapid thermal oxidation chambers, one or more plasma oxidation and/or nitridation chambers, one or more PVD chambers, one or more annealing chambers and/or any other suitable chambers that may be used to form the tunnel layers 104 and/or 105 on the substrate. The tunnel layers 104 and 105 are used as tunnel junction layers that passivate the interface between the subsequently deposited polysilicon layer(s) and the substrate 102. The tunnel layers 104 and 105 are also used to block dopant diffusion to form a hyperabrupt junction at the interface between the polysilicon layers 106, 108 and the substrate 102. Without the tunnel layers, dopants in the polysilicon layers 106 and 108 may diffuse to the substrate 102 and cause an undesired doping profile for the solar cell 100. In general, the tunnel layers are formed so that the electrical current passing through the tunnel layer, between the substrate and polysilicon layer (e.g., emitter), is completed primarily by a “tunneling” process and not the conductivity of the tunnel layer material. Since the electrical current has to pass through the tunnel layer, the tunnel layer thickness has to be small (e.g., silicon dioxide having a thickness of 8-12 Å) to reduce the junctions electrical resistance. In one embodiment, tunnel layers are formed either by growing a silicon dioxide layer and implanting nitrogen to form an oxy-nitride, or by thermally growing a silicon nitride layer on silicon or on a thin silicon dioxide film. In one embodiment, the tunnel layers 104 and 105 are less than about 15 Å thick. In another embodiment, the tunnel layers 104 and 105 are less than about 12 Å thick. In one embodiment, the tunnel layers 104 and 105 are between about 8 Å and about 12 Å thick. An exemplary process of forming a solar cell device that use a polysilicon emitter structure having tunnel layers is further described in the United States Provisional Patent Application entitled “Nitrided Gates For Polysilicon Emitter Solar Cells”, filed Apr. 9, 2008, which is incorporated by reference in its entirety. In one embodiment, as shown in FIG. 3, a transfer conveyor 310 is used to transport the substrate from the wet cleaning chamber 312 to a substrate loader 304 that is coupled to the deposition system 322. In one embodiment, the deposition system 322 is cluster tool having a plurality of rapid thermal oxidation and/or plasma nitridation chambers capable of forming one or more desired layers on the substrate surface. Suitable rapid thermal oxidation, plasma nitridation, and plasma enhanced chemical vapor deposition chambers are available from Applied Materials, Inc., located in Santa Clara, Calif.

In step 205, a first polysilicon layer 106 is formed on the tunnel layer 104, which is formed on the front side of the substrate 102. In one embodiment, the process of depositing the polysilicon layer 106 is performed using a silicon-based gas, a hydrogen-based gas and a dopant containing gas that is deposited using a plasma enhanced chemical vapor deposition (PECVD) process, thermal CVD process, or other suitable deposition process. Suitable silicon based gases include, but are not limited to, silane (SiH₄), disilane (Si₂H₆), silicon tetrafluoride (SiF₄), silicon tetrachloride (SiCl₄), dichlorosilane (SiH₂Cl₂), and combinations thereof. Suitable hydrogen-based gases include, but are not limited to hydrogen gas (H₂). In one embodiment, the polysilicon layer 106 contains a p-type dopant and the substrate 102 contains an n-type dopant. Typically, the p-type dopants contained in a p-type polysilicon layer 106 may comprise a group III element, such as boron or aluminum. In one example, boron is used as the p-type dopant. Examples of boron-containing sources include trimethylboron (TMB), diborane (B₂H₆), B(C₂H₅)₃, BH₃, BF₃, and B(CH₃)₃ and similar compounds. In another example, TMB is used as the p-type dopant. In another embodiment, the polysilicon layer 106 contains an n-type dopant and the substrate 102 contains a p-type dopant. Typically, the n-type polysilicon layer 106 may comprise a group V element, such as phosphorus, arsenic, or antimony. Examples of phosphorus-containing sources include phosphine and similar compounds. The dopant containing gases are typically provided with a carrier gas, such as hydrogen, argon, helium, and other suitable compounds. While step 205 discusses the use of a PECVD or thermal CVD process to form a doped polysilicon layer 106 this configuration is not intended to limiting as to the scope of the invention, since other processes sequences could be used to form a doped polysilicon layers 106 without deviating from the basic scope of the invention described herein.

In step 206, an optional second polysilicon layer 108 is formed on the tunnel layer 105, which is disposed on the back side of the substrate 102. In one embodiment, the process of depositing the polysilicon layer 108 is performed using a silicon-based gas, a hydrogen-based gas and a dopant containing gas that is deposited using a plasma enhanced chemical vapor deposition (PECVD) process, thermal CVD process, or other suitable deposition process. The process of forming the polysilicon layer 108 is generally similar to the process described above. In one embodiment, the polysilicon layer 108 comprises a p-type degenerately doped layer and the substrate 102 contains a p-type dopant. In another embodiment, the polysilicon layer 108 comprises an n-type degenerately doped layer and the substrate 102 contains an n-type dopant.

In one embodiment of steps 205 and step 206, a transfer conveyor 310 is used to transport the substrate from the deposition system 322 to a substrate loader 304 that is coupled to a deposition system 332 that is disposed in the production line 300. In one embodiment, the deposition system 332 may comprise one or more chemical vapor deposition (CVD) chambers, one or more PVD chambers, one or more annealing chambers and/or any other suitable chambers that may be used to deposit the first polysilicon layer 106 and the optional second polysilicon layer 108 on the substrate. In one embodiment, the deposition system 332 is cluster tool having a plurality of plasma enhanced chemical vapor deposition (PECVD) chambers 323 capable of depositing one or more desired layers on the substrate surface. It is contemplated that other deposition chambers, such as hot wire chemical vapor deposition (HWCVD), low pressure chemical vapor deposition (LPCVD), physical vapor deposition (PVD), evaporation, or other similar devices, including those from other manufacturers, may be utilized to practice the present invention. In another embodiment of the production line 300, the processing chambers found in the deposition systems 322 and 332 are all positioned on one system, and each of the processing chambers are adapted to perform step 203, step 205 and/or step 206. After the desired film layers are formed on the substrate surface, the substrate may be unloaded from the deposition system 332 through a substrate unloader 306 and transferred back to a transfer conveyor 310 so that it can be transferred to the next process module disposed in the production line 300.

In step 207, a densification process is performed on the polysilicon layer 106 to cause the material in the polysilicon layer 106 to become more dense, reduce its sheet resistance and improve the optical transmission of the formed layer. In one example the densification process is performed at a temperature between about 750 and about 1200° C. In one embodiment of step 207, a rapid thermal anneal (RTA) densification process step is performed in an inert gas and/or forming gas containing environment.

In one embodiment of steps 207, a transfer conveyor 310 is used to transport the substrate from the deposition system 332 to a substrate loader 304 that is coupled to a deposition system 342 that is disposed in the production line 300. In one embodiment, the deposition system 332 may comprise one or more one or more annealing chambers (e.g., furnace, rapid thermal anneal chamber) and/or any other suitable chambers that may be used to perform step 207. In one embodiment, the deposition system 332 is cluster tool having a plurality of rapid thermal annealing chambers capable of perform step 207. In another embodiment of the production line 300, the processing chambers found in the deposition systems 322, 332 and 342 are all positioned on one system, and each of the processing chambers are adapted to perform steps 203, 205, 206 and/or 207. After the performing step 207, the substrate may be unloaded from the deposition system 342 through a substrate unloader 306 and transferred back to a transfer conveyor 310 so that it can be transferred to the next process module disposed in the production line 300.

In an alternate embodiment of step 207, a passivating layer 109 is formed on the surface of the polysilicon layer 106. In one implementation, the passivating layers 109 and 112 are both formed on the first and the second polysilicon layers 106 and 108, respectively. The passivating layers 109 and 112 may comprise a silicon oxide, a silicon nitride, a silicon oxynitride or combinations thereof. In one implementation, forming the passivating layers 109 and/or 112 includes flowing oxygen, oxygen-hydrogen, or oxygen-water into a processing chamber (not shown) where the substrate 102 with the polysilicon layers 106 and/or 108 is placed, before heating the inflow oxygen, oxygen-hydrogen, or oxygen-water to a predetermined temperature for a predetermined period of time. In one example, the predetermined temperature is about 1000° C., while the predetermined period of time is about 30 seconds. The flowing of the gas/fluid and the heating thereof could be performed in one step or in multiple steps. It is worth noting that the properties of the passivating layers 109 and 112 can vary with the time and temperature used to form the passivating layers 109 and 112 and thus different passivating layer thicknesses can be used to perform the same device function. Depending on the temperature and time the growth rate of the passivating layer 109 will vary. For example, the thickness of the passivating layer 109 could be around 30-40 Å when it is formed using an oxygen source gas, which is heated to about 1000° C. for about 30 seconds. In another example, a 30-40 Å thick passivating layer 109 could be formed by delivering an oxygen source gas, which is heated to about 850° C. for about 240 seconds. The oxygen source gas may include nitrous oxide (N₂O), oxygen (O₂), water (H₂O), carbon dioxide (CO₂), forming gas (3H₂+N₂), and combinations thereof. The thickness of the passivating layer 109 might grow to about 50-60 Å when oxygen and water mixture are used. Meanwhile, in one implementation the thickness of the passivating layer 112 could be no more than about 12 Å. It is worth noting that the formation of the passivating layers 109 and 112 using the alternate embodiment of step 207 requires no additional steps in a currently existing solar cell manufacturing process, which include a step of densification using RTA to reduce sheet resistance and optical absorption of the polysilicon layers. More specifically, the alternate version of step 207, which includes the formation of a passivating layer, replaces the aforementioned step of densification using a rapid thermal anneal (RTA) process. Thus, in one embodiment, step 207 may use rapid thermal oxidation (RTO) to grow a thin passivation oxide while also densifying the passivating layers 109 and/or 112. Alternatively, step 207 may grow a rapid thermal nitride or a combination thereof.

The formation of the passivating layers 109 and 112 could also be accomplished using other different formation process steps. In one implementation, a plasma oxidation process is performed at a temperature lower than 1000° C. to form one or more of the passivating layers just after forming the first polysilicon layer 106 and/or the optional second polysilicon layer 108. In one implementation, a plasma oxidation process is performed using a radio frequency (RF) plasma at a temperature lower than 450° C. to form one or more of the passivating layers. In one example, the RF plasma is formed over a surface of a substrate using a capacitively coupled and/or inductively coupled source that is driven a frequency between about 300 kHz and about 10 GHz, such as about 13.56 MHz. In one configuration, the plasma oxidation step is performed in a processing region of a plasma enhanced chemical vapor deposition (PECVD) chamber using an oxygen containing gas after the first polysilicon layer 106 and/or the second polysilicon layer 108 are formed. In one configuration, the passivating layer 109 is formed on the first polysilicon layer 106 using a plasma oxidation process after the first polysilicon layer 106 deposition step has been performed in the same PECVD chamber. In one example, the passivating layer 109 is formed on the first polysilicon layer 106 at the end of the first polysilicon layer 106 deposition step. In one embodiment, the oxygen containing gas may include nitrous oxide (N₂O), oxygen (O₂), water (H₂O), carbon dioxide (CO₂) and combinations thereof. In one embodiment, after forming the passivating layers 109 and/or 112 using the plasma oxidation process, an RTA densification process step (e.g., step 207) is performed. In one embodiment, the RTA densification process step is performed in a forming gas containing environment.

In step 209, the process 200 forms the anti-reflection (AR) layer 114 over the passivating layer 109 on the front side of the substrate 102. In one embodiment, the AR layer 114 may be a silicon oxide, a silicon nitride, hafnium oxide, hafnium silicon oxide, hafnium silicon oxynitride, lanthanum oxide, lanthanum silicon oxide, lanthanum oxynitride, aluminum oxide or a combination thereof. In another embodiment, the AR layer 114 may be deposited by using LPCVD (Low Pressure Chemical Vapor Deposition), sputtering process, or PECVD process.

In order to carry away the electric current produced during normal operation of the solar cell, metal contacts may be applied to the front and back sides of the substrate 102. Suitable metals may include, but are not limited to, silver, copper, nickel, vanadium and aluminum (including alloys thereof).

In one embodiment of step 207 and step 209, a transfer conveyor 310 is used to transport the substrate from the deposition system 332 to a substrate loader 304 that is coupled to a deposition system 342 that is disposed in the production line 300. In one embodiment, the deposition system 342 may comprise one or more LPCVD chambers, one or more PECVD chambers, one or more PVD chambers, one or more one or more annealing chambers (e.g., furnace, rapid thermal anneal chamber) and/or any other suitable chambers that may be used to perform steps 207-209. In one embodiment, the deposition system 342 is cluster tool having a plurality of plasma enhanced chemical vapor deposition (PECVD) chambers 323 capable of depositing one or more desired layers on the substrate surface. It is contemplated that other deposition chambers, such as hot wire chemical vapor deposition (HWCVD), low pressure chemical vapor deposition (LPCVD), physical vapor deposition (PVD), evaporation, or other similar devices, including those from other manufacturers, may be utilized to practice the present invention. In another embodiment of the production line 300, the processing chambers found in the deposition systems 322, 332 and 342 are all positioned on one system, and each of the processing chambers are adapted to perform steps 203, 205, 206, 207 and/or step 209. After the performing steps 207-209, the substrate may be unloaded from the first deposition system 342 through a substrate unloader 306 and transferred back to a transfer conveyor 310 so that it can be transferred to the next process module disposed in the production line 300.

In step 211, the back contact 118 is formed on the back side of the substrate 102. The back contact layer 118, is typically deposited by use of a sputtering (PVD), metal CVD, evaporation process, or other suitable processing techniques used to from a metal contact layer on the surface of the substrate 102. In one example, the back contact layer 118 is an aluminum layer deposited using a sputtering process.

In step 213, the process 200 forms the metal contacts 116 on the front side of the substrate 102. In one implementation, the metal contacts 116 may be obtained by means of screen-printing, pattern and lift-off techniques or other suitable processing techniques used to from a patterned metal contact layer on the front surface of the substrate 102. In one example, a screen printing paste containing metallic powder may be deposited on the front side of the substrate 102. Desired patterns of the metal contacts 116 are then formed by use of photo-patterning technique on the screen printing paste. The metal contacts 116 are then formed by firing on the dried screen printing paste to desired pattern. Alternatively, the metal contact 116 on the front side of the substrate 102 may also be obtained by metal evaporation. The front side of the substrate 102 may be deposited with titanium palladium silver (TiPdAg). The TiPdAg then may be removed by evaporation under a high volume vacuum deposition evaporators to obtain the desired metal contact 116.

In one embodiment of step 211 and step 213, a transfer conveyor 310 is used to transport the substrate from the deposition system 342 to a substrate loader 304 that is coupled to a deposition system 352 that is disposed in the production line 300. In one embodiment, the deposition system 352 may comprise one or more CVD chambers, one or more PVD chambers, and/or any other suitable chambers that may be used to perform steps 211-213. In one embodiment, the deposition system 352 is cluster tool having processing chambers 323, such as PVD chambers, capable of depositing one or more desired layers on the substrate surface. It is contemplated that other processing chambers, such as an evaporation chamber or other similar devices, including those from other manufacturers, may be utilized to practice the present invention. In another embodiment of the production line 300, the processing chambers found in the deposition systems 322, 332, 342 and 352 are all positioned on one system, and each of the processing chambers are adapted to perform steps 203, 205, 206, 207, 209, 211 and/or 213. After the performing step 213, the substrate may be unloaded from the first deposition system 352 through a substrate unloader 306 and transferred back to a transfer conveyor 310 so that it can be transferred to the next process module disposed in the production line 300. In one embodiment of the production line 300, after all the processes have been performed on the substrate surface, the substrate may be tested and inspected in the cell tester 380 (e.g., automated optical inspection, electrical resistance measurements, film thickness, particles) and then sorted in the cell sorter 382. The cell tester 380 and the cell sorter 382 are generally used to assure that the results of the process steps 201-213 are within specification and that the substrates appropriately grouped. An example of a deposition system and process chambers that may be adapted to perform one or more of the steps 203, 205, 206, 207, 209, 211 or 213 on one or more substrates at a time are the AKT-4300 PECVD or AKT-5500 PECVD tools, which are both available from Applied Materials, Inc. of Santa Clara Calif.

While the foregoing is directed to embodiments of the invention, other and further embodiments of the invention thus may be devised without departing from the basic scope thereof, and the scope thereof is determined by the claims that follow.

1. A method for forming a solar cell device, comprising:
forming a tunnel layer on a first surface of a substrate, wherein the first tunnel layer comprises a dielectric material;
forming a first polysilicon layer over the tunnel layer;
heating the first polysilicon layer to a first temperature, wherein the first temperature is adapted to cause the formed polysilicon layer to densify; and
forming a first passivating layer over the first polysilicon layer.

2. The method of claim 1, wherein the step of forming the first passivating layer comprises flowing an oxygen containing gas into a processing chamber while heating the polysilicon layer to the first temperature.

3. The method of claim 2, wherein the first temperature is about 1000° C. and the predetermined period of time is about 30 seconds.

4. The method of claim 1, wherein the step of forming the first passivating layer comprises flowing oxygen and a gas comprising hydrogen.

5. The method of claim 1, further comprising forming a second polysilicon layer over a second surface of the substrate, wherein the first and second surfaces are on opposite sides of the substrate.

6. The method of claim 1, wherein the dielectric material has a thickness less than 12 Angstroms, and the dielectric material comprises silicon and oxygen or nitrogen.

7. The method of claim 5, further comprising forming a second passivating layer over the second polysilicon layer.

8. The method of claim 5, further comprising forming contacts over the first and the second polysilicon layers.

9. The method of claim 1, further comprising forming an anti-reflection layer over the first passivating layer.

10. The method of claim 1, wherein the step of forming the first passivating layer comprises:
disposing a substrate in a processing region of a processing chamber;
flowing an oxygen containing gas into the processing region; and
generating an RF plasma in the processing region, wherein the first passivating layer and the first polysilicon layer are both formed in the processing region of the processing chamber, and the first passivating layer is formed before removing the substrate from the processing region after forming the first polysilicon layer.

11. A solar cell device, comprising:
a crystalline silicon substrate;
a first tunnel layer disposed over a first surface of the crystalline silicon substrate;
a first polysilicon layer disposed over the first tunnel layer; and
a first passivating layer disposed over the first polysilicon layer.

12. The solar cell device of claim 11, further comprising a second polysilicon layer disposed over a second surface of the crystalline silicon substrate, wherein the first and second surfaces are on opposite sides of the crystalline silicon substrate.

13. The solar cell structure of claim 12, further comprising a second tunnel layer disposed between the crystalline silicon substrate and the second polysilicon layer.

14. The solar cell structure of claim 12, further comprising a second passivating layer over the second polysilicon layer.

15. The solar cell structure of claim 14, wherein the first passivating layer is thicker than the second passivating layer.

16. The solar cell structure of claim 11, wherein the first tunnel layer is less than about 12 Å in thickness.

17. The solar cell structure of claim 16, wherein the first tunnel layer comprises a material selected from the group consisting of silicon oxide, silicon nitride, silicon oxynitride, and silicon oxycarbon nitride.

18. The solar cell structure of claim 11, wherein the first and the second passivating layers comprise silicon dioxide.

19. The solar cell structure of claim 11, further comprising an anti-reflection layer disposed over the first passivating layer.

20. An apparatus for forming solar cell device, comprising:
a wet processing chamber that is configured to immerse a solar cell substrate into a cleaning solution;
a first cluster tool having at least one processing chamber that is adapted to form a polysilicon layer on a first surface of the solar cell substrate;
a second cluster tool having at least one thermal processing chamber adapted to cause the formed polysilicon layer to densify; and
a conveyor assembly configured to serially transfer the solar cell substrate to the wet processing chamber, the first cluster tool and the second cluster tool.
